(19) United States
(12) Patent Application Publication
(10) Pub. No.: US 2024/0223138 A1
(43) Pub. Date: Jul. 4, 2024

(54) OVERCURRENT PROTECTION CIRCUIT AND POWER AMPLIFIER INCLUDING THE SAME

(71) Applicant: SAMSUNG ELECTRO-MECHANICS CO., LTD., Suwon-si (KR)

(72) Inventors: Kyung Hee HONG, Suwon-si (KR); Yoshiyuki TONAMI, Suwon-si (KR); Kyujin CHOI, Suwon-si (KR); Suyeon HAN, Suwon-si (KR); Geunyong LEE, Suwon-si (KR); Seungchul PYO, Suwon-si (KR)

(73) Assignee: SAMSUNG ELECTRO-MECHANICS CO., LTD., Suwon-si (KR)

(21) Appl. No.: 18/301,321

(22) Filed: Apr. 17, 2023

(30) Foreign Application Priority Data
Dec. 30, 2022 (KR) 10-2022-0190859
Apr. 3, 2023 (KR) 10-2023-0043568

(51) Int. Cl. H03F 3/24; H03F 1/08; H04B 1/04

(52) U.S. Cl. CPC H03F 3/245; H03F 1/083; H04B 1/0466; H03F 2200/451

(57) ABSTRACT

A power amplifier overcurrent protection circuit is provided. The overcurrent protection circuit protects a power amplifier that receives a bias current from a bias circuit and amplifies an input radio frequency (RF) signal. The current protection circuit includes an envelope detector configured to detect an envelope for a first voltage corresponding to an input radio frequency (RF) signal, a first transistor configured to receive a value of the envelope through a control terminal of the first transistor and turn on based on the value of the envelope to sink a current from a first node of a bias circuit, and a second transistor connected between a power source and the first transistor and including a control terminal connected to the first node of the bias circuit.

### CROSS-REFERENCE TO RELATED APPLICATIONS

This application claims the benefit under 35 USC § 119(a) of Korean Patent Application Nos. 10-2022-0190859 and 10-2023-0043568 filed on Dec. 30, 2022 and Apr. 3, 2023, in the Korean Intellectual Property Office, the entire contents of which are incorporated herein by reference for all purposes.

### BACKGROUND

### 1. Field

The following description relates to an overcurrent protection circuit, and a power amplifier including the same.

### 2. Description of Related Art

Transmitters that are implemented in wireless communication systems may include a power amplifier that amplifies a radio frequency (RF) signal to increase a transmission distance of the signal.

The power amplifier may require high reliability, and it is desirable that the power amplifier should not be damaged under conditions where a large input signal is applied and a load is largely changed.

An excessive current may flow under a specific condition where an input signal of excessive power is applied, and a load is largely changed. In this example, when an overcurrent exceeding a limit flows in a driver stage or a power stage configuring the power amplifier, a phenomenon in which an element is damaged occurs.

Therefore, it may be beneficial to have a protection circuit that prevents the power amplifier from being damaged by an overcurrent even under harsh conditions outside of normal operations of the power amplifier.

The above information disclosed in this Background section is only for enhancement of an understanding of the background of the described technology, and therefore it may contain information that does not constitute prior art.

### SUMMARY

This Summary is provided to introduce a selection of concepts in a simplified form that is further described below in the Detailed Description. This Summary is not intended to identify key features or essential features of the claimed subject matter, nor is it intended to be used as an aid in determining the scope of the claimed subject matter.

In a general aspect, a power amplifier overcurrent protection circuit includes an envelope detector configured to detect an envelope for a first voltage corresponding to an input radio frequency (RF) signal; a first transistor configured to receive a value of the envelope through a control terminal of the first transistor and turn on based on the value of the envelope to sink a current from a first node of a bias circuit; and a second transistor connected between a power source and the first transistor and including a control terminal connected to the first node of the bias circuit.

The bias circuit may include a third transistor configured to supply the bias current, and the first node may be connected to a control terminal of the third transistor.

The bias circuit may further include a fourth transistor and a fifth transistor that are stacked between the first node and a ground.

The envelope detector may include a first resistor configured to adjust a turn-on voltage level of the first transistor from an envelope for the first voltage.

The envelope detector may further include a diode, wherein the first voltage may be inputted to an anode of the diode, and a cathode of the diode may be connected to a first terminal of the first resistor; a capacitor, wherein a first terminal of the capacitor may be connected to the cathode of the diode, and a second terminal of the capacitor may be connected to a ground; and a second resistor connected between a second terminal of the first resistor and the ground, and the second terminal of the first resistor may be connected to the control terminal of the first transistor.

The power amplifier may include a power transistor configured to amplify and output the input RF signal; wherein a first voltage corresponding to the input RF signal may be a voltage of an RF signal amplified by the power transistor; and wherein the bias circuit may be configured to supply the bias current to the power transistor.

The power amplifier may include a driver transistor configured to receive a first bias current and amplify and output the input RF signal; and a power transistor configured to receive a second bias current and amplify and output an RF signal amplified by the driver transistor, and wherein a first voltage corresponding to the input RF signal is a voltage of an RF signal amplified by the driver transistor.

The bias circuit may include a first bias circuit configured to supply the first bias current; and a second bias circuit configured to supply the second bias current, and wherein the first transistor is configured to turn on based on the envelope value to sink a current from the first bias circuit and the second bias circuit.

The first bias circuit may include a third transistor configured to supply the first bias current; the second bias circuit may include a fourth transistor configured to supply the second bias current; and the control terminal of the second transistor may be connected to a control terminal of the third transistor and a control terminal of the fourth transistor.

In a general aspect, a power amplifier includes a first transistor configured to amplify a radio frequency (RF) signal; a first bias circuit comprising a second transistor configured to supply a first bias current to the first transistor; an envelope detector configured to detect an envelope for a first voltage corresponding to the RF signal; and a protection circuit part configured to reduce the first bias current by sinking a current from the first bias circuit when a value of the envelope is equal to or greater than a set value, wherein the protection circuit part includes a third transistor configured to receive the value of the envelope through a control terminal of the third transistor, and including a first terminal, and a second terminal connected to a ground; and a fourth transistor including a control terminal connected to a control terminal of the second transistor, a first terminal connected to a power source, and second terminal connected to the first terminal of the third transistor.

The power amplifier may further include a fifth transistor configured to amplify the RF signal, and transmit the RF signal to the first transistor; and a second bias circuit comprising a sixth transistor configured to supply a second bias current to the fifth transistor, wherein the first voltage corresponding to the input RF signal is a voltage of an RF signal amplified by the fifth transistor.

The control terminal of the fourth transistor may be connected to a control terminal of the second transistor and a control terminal of the sixth transistor.

The first voltage corresponding to the input RF signal may be a voltage of an RF signal amplified by the first transistor.

The envelope detector may include a resistor configured to adjust a turn-on voltage level of the third transistor from an envelope for the first voltage.

The first bias circuit may further include a fifth transistor and a sixth transistor that are stacked between a control terminal of the second transistor and the ground.

In a general aspect, a power amplifier includes a first transistor and a second transistor configured to amplify an input radio frequency (RF) signal; one or more bias circuits configured to generate bias currents, and supply the generated bias currents to the first transistor and the second transistor; an envelope detector, configured to detect a voltage of an output RF signal of the first transistor or an output RF signal of the second transistor; and a protection circuit, comprising a third transistor, and configured to sink a current from the one or more bias circuits when the detected voltage is greater than or equal to a predetermined value; wherein a control terminal of the third transistor is connected to an output terminal of the envelope detector.

The envelope detector may include a resistor that is connected the control terminal of the third transistor, and the resistor is configured to adjust a turn-on voltage of the third transistor.

The protection circuit may include a fourth transistor including a control terminal to which the current sunk from the at least one bias circuit is input, a first terminal connected to a first terminal of the third transistor, and a second terminal connected to a power.

Other features and aspects will be apparent from the following detailed description, the drawings, and the claims.

### BRIEF DESCRIPTION OF DRAWINGS

FIG. 1 illustrates an example multi-stage power amplifier 1000, in accordance with one or more embodiments.

FIG. 2 illustrates an example multi-stage power amplifier 1000a, in accordance with one or more embodiments.

FIG. 3 illustrates an example power amplifier 1000b, in accordance with one or more embodiments.

FIG. 4 illustrates an example first bias circuit 710 shown in FIG. 1.

FIG. 5 illustrates an example second bias circuit 720 shown in FIG. 1.

FIG. 6 illustrates an example overcurrent protection circuit 800 shown in FIG. 1.

FIG. 7 illustrates an example input RF signal waveform applied to a base of an example driver transistor shown in FIG. 1.

FIG. 8 illustrates an example of an envelope detected by an example envelope detector shown in FIG. 6.

FIG. 9 illustrates a graph of a simulation result for a current I3 shown in FIG. 6.

FIG. 10 illustrates a graph of a simulation result for a bias current (I_{BIAS2}) shown in FIG. 6.

FIG. 11 illustrates a graph of a simulation result for a current (Iₛᵢₙₖ) shown in FIG. 6.

FIG. 12 illustrates a graph of a simulation result for a current I5 shown in FIG. 6.

FIG. 13 illustrates a graph of a simulation result for a current (I_{CC}) shown in FIG. 6.

FIG. 14 illustrates an overcurrent protection circuit 800a shown in FIG. 2.

FIG. 15 illustrates an overcurrent protection circuit 800b shown in FIG. 3.

Throughout the drawings and the detailed description, the same reference numerals may refer to the same, or like, elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known, after an understanding of the disclosure of this application, may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween. Likewise, expressions, for example, “between” and “immediately between” and “adjacent to” and “immediately adjacent to” may also be construed as described in the foregoing.

The terminology used herein is for the purpose of describing particular examples only, and is not to be used to limit the disclosure. As used herein, the singular forms “a,” “an,” and “the” are intended to include the plural forms as well, unless the context clearly indicates otherwise. As used herein, the term “and/or” includes any one and any combination of any two or more of the associated listed items. As used herein, the terms “include,” “comprise,” and “have” specify the presence of stated features, numbers, operations, elements, components, and/or combinations thereof, but do not preclude the presence or addition of one or more other features, numbers, operations, elements, components, and/or combinations thereof. The use of the term “may” herein with respect to an example or embodiment (for example, as to what an example or embodiment may include or implement) means that at least one example or embodiment exists where such a feature is included or implemented, while all examples are not limited thereto.

Unless otherwise defined, all terms, including technical and scientific terms, used herein have the same meaning as commonly understood by one of ordinary skill in the art to which this disclosure pertains consistent with and after an understanding of the present disclosure. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

Throughout the specification, the RF signal may have a format according to other random wireless and wired protocols designated by, as only examples, Wi-Fi (IEEE 802.11 family, etc.), WiMAX (IEEE 802.16 family, etc.), IEEE 802.20, long term evolution (LTE), Evolution-Data Optimized (Ev-DO), high-speed packet access plus (HSPA+), high-speed downlink packet access plus (HSDPA+), high-speed uplink packet access plus (HSUPA+), Enhanced Data GSM Evolution (EDGE), Global System for Mobile communication (GSM), Global Positioning System (GPS), General Packet Radio Service (GPRS), Code Division Multiple Access (CDMA), Time Division Multiple Access (TDMA), digital enhanced cordless communication (DECT), Bluetooth, third generation (3G), fourth generation (4G), fifth generation (5G), and any other wireless and wired protocols designated thereafter, but is not limited thereto.

One or more examples may provide an overcurrent protection circuit that may prevent an excessive current from flowing through a power amplifier.

In accordance with one or more examples, when an excessive RF input signal is inputted, it is possible to prevent a power amplifier from being damaged by reducing a bias current applied to a driver stage and/or a power stage configuring the power amplifier.

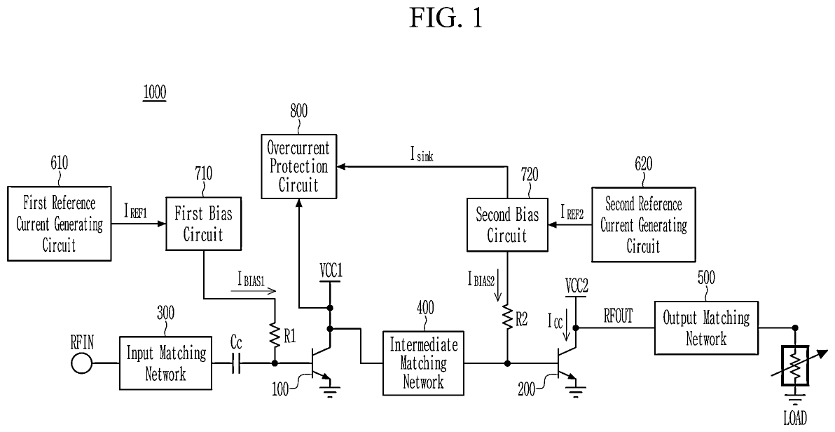

FIG. 1 illustrates an example multi-stage power amplifier 1000, in accordance with one or more embodiments.

Referring to FIG. 1, the example multi-stage power amplifier 1000 is configured of two stages. The example multi-stage power amplifier 1000 includes a driver transistor 100 of a first stage amplifier, a power transistor 200 of a second stage amplifier, an input matching network 300, an intermediate matching network 400, an output matching network 500, a first reference current generating circuit 610, a second reference current generating circuit 620, a first bias circuit 710, a second bias circuit 720, and an overcurrent protection circuit 800.

In an example, the first stage amplifier may be a driver amplifier (DA), which has a high gain and transmits a radio frequency (RF) signal level suitable for the second stage amplifier. The first stage amplifier may include the driver transistor 100.

In an example, the second stage amplifier may be a power amplifier (PA), and may generate high power that may be needed by a system. The second stage amplifier may include the power transistor 200.

The input matching network 300 may be connected to an input terminal (that is, a base) of the driver transistor 100, and the input matching network 300 may perform impedance matching between an input radio frequency (RF) signal RFIN and the driver transistor 100.

The intermediate matching network 400 may be connected to an output terminal (that is, a collector) of the driver transistor 100, and the intermediate matching network 400 may perform impedance matching between an output RF signal of the driver transistor 100 and the power transistor 200.

The output matching network 500 may be connected to an output terminal (that is, a collector) of the power transistor 200, and the output matching network 500 may perform impedance matching between an output RF signal RFOUT of the power transistor 200 and a load.

The input matching network 300, the intermediate matching network 400, and the output matching network 500 may each be implemented as a combination of at least one of a resistor, an inductor, and a capacitor, as only examples.

The driver transistor 100 may amplify power for the RF signal RFIN inputted to the input terminal thereof (that is, the base) of the driver transistor 100, and then output the RF signal to an output terminal thereof (that is, the collector). That is, an RF signal to be amplified may be inputted to the base of the driver transistor 100, and the collector of the driver transistor 100 may output the amplified RF signal. An emitter of the driver transistor 200 may be connected to the ground, and although not shown in FIG. 1, a resistor may be additionally connected between the emitter of the driver transistor 200 and the ground. Additionally, the collector of the driver transistor 100 may be connected to a power source voltage VCC1, and the power transistor 100 may be operated based on the power source voltage VCC1.

The output RF signal of the driver transistor 100 is inputted to the input terminal (that is, the base) of the power transistor 200 via the intermediate matching network 400. The power transistor 200 may amplify power for an RF signal inputted to the input terminal thereof and then output it to the output terminal (that is, the collector) of the power transistor 200 thereof. That is, an RF signal to be amplified may be inputted to the base of the power transistor 200, and the collector of the power transistor 200 may output the amplified RF signal. An emitter of the power transistor 200 may be connected to the ground, and, in a non-limiting example, a resistor may be additionally connected between the emitter of the power transistor 200 and the ground. Additionally, the collector of the power transistor 200 may be connected to a power source voltage VCC2, and the power transistor 200 may be operated based on the power source voltage VCC2.

The driver transistor 100 and the power transistor 200 may be each realized as various transistors such as, but not limited to, a heterojunction bipolar transistor (HBT), a bipolar junction transistor (BJT), and an insulated gate bipolar transistor (IGBT). Additionally, although the power transistor 200 is illustrated as an n-type transistor in FIG. 1, this is only an example, and it may be replaced with a p-type transistor. On the other hand, since the base of the transistor operates as a control terminal, the base of the transistor may be referred to as a ‘control terminal’. Since the collector of the transistor is one terminal of the transistor, it may be referred to as a ‘first terminal or second terminal’. Additionally, since the emitter of the transistor is one terminal of the transistor, it may be referred to as a ‘first terminal or second terminal’.

In an example, a coupling capacitor Cc may be connected to the input terminal (that is, the base) of the driver transistor 100. The coupling capacitor Cc may perform an operation of blocking a direct current (DC) component from the input RF signal.

The first bias circuit 710 may receive a reference current I_{REF1} from the first reference current generating circuit 610, and generate a bias current I_{BIAS1} needed by the driver transistor 100. The bias current I_{BIAS1} is supplied to the input terminal of the driver transistor 100, and a bias level (bias point) of the driver transistor 100 may be set by the bias current I_{BIAS1}.

A resistor R1 may be connected between the first bias circuit 710 and the input terminal of the driver transistor 100.

The first reference current generating circuit 610 may generate the reference current I_{REF1} and supply the generated reference current I_{REF1} to the first bias circuit 710.

The second bias circuit 720 may receive a reference current I_{REF2} from the second reference current generating circuit 620, and generate a bias current I_{BIAS2} needed by the power transistor 200. The bias current I_{BIAS2} may be supplied to the input terminal (or base) of the power transistor 200, and a bias level (bias point) of the power transistor 200 may be set by the bias current I_{BIAS2}. In this example, the bias current I_{BIAS2} may be reduced by the overcurrent protection circuit 800. When the bias current I_{BIAS2} is reduced, a current I_{CC} flowing through the output terminal (that is, the collector) of the power transistor 200 may be reduced.

A resistor R2 may be additionally connected between the second bias circuit 720 and the input terminal (or base) of the power transistor 200.

The second reference current generating circuit 620 may generate the reference current I_{REF2} and supply the generated the reference current I_{REF2} to the second bias circuit 720.

Referring to FIG. 1, a current flowing through the output terminal (that is, the collector) of the power transistor 200 is denoted as I_{CC}. In an example, the current I_{CC} may be an output current of the power amplifier 1000.

As the input RF signal RFIN increases, a current flowing through each stage of the power amplifier 1000 also increases. Load mismatch may occur under certain situations. As a result, an excessive current I_{CC} flows through the power amplifier 1000, and an example in which an element of each stage of the power amplifier 1000 exceeds a current limit that may be tolerated occurs.

The power amplifier overcurrent protection circuit 800, in accordance with one or more embodiments, may detect a voltage corresponding to the input RF signal RFIN, and may operate when the detected voltage is greater than or equal to a set value. In this example, the overcurrent protection circuit 800 sinks a current as much as a current Iₛᵢₙₖ received from the second bias circuit 720 to reduce the bias current I_{BIAS2}, thereby preventing an overcurrent from flowing through the power transistor 200.

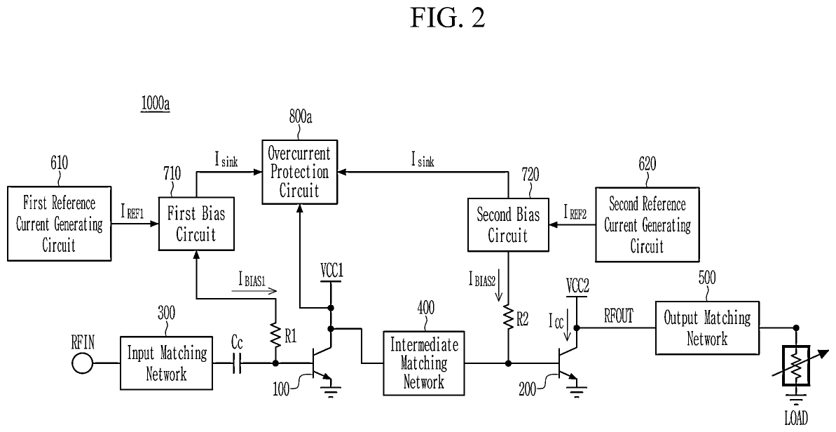

FIG. 2 illustrates an example multi-stage power amplifier 1000a, in accordance with one or more embodiments.

Referring to FIG. 2, the example multi-stage power amplifier 1000a may have a configuration similar to the configuration of the example multi-stage power amplifier 1000 of FIG. 1.

However, in the example illustrated in FIG. 2, an overcurrent protection circuit 800a detects a voltage corresponding to the input RF signal RFIN, and when the detected voltage is greater than a set value, it may sink a current as much as the current Iₛᵢₙₖ from the second bias circuit 720 and sink a current as much as the current Iₛᵢₙₖ from the first bias circuit 710. That is, the overcurrent protection circuit 800a may control, not only the bias current I_{BIAS2} of the second bias circuit 720 but also the bias current I_{BIAS1} of the first bias circuit 710.

Additionally, in an example, the overcurrent protection circuit 800 of FIG. 1 or the overcurrent protection circuit 800a of FIG. 2 may be applied to a multi-stage amplifier having three or more stages.

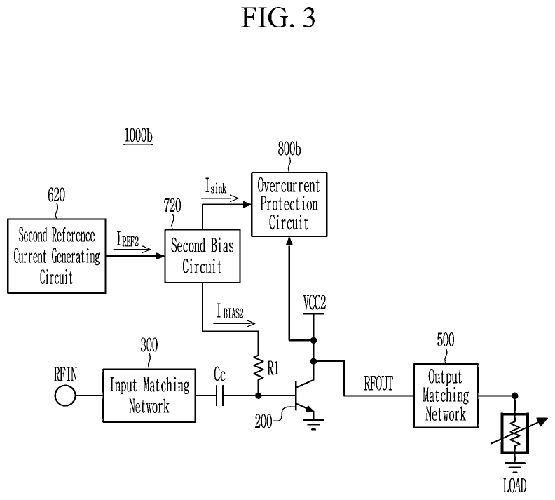

FIG. 3 illustrates an example power amplifier 1000b, in accordance with one or more embodiments.

Referring to FIG. 3, unlike the respective multi-stage power amplifiers 1000 and 1000a of FIG. 1 and FIG. 2, the power amplifier 1000b of FIG. 3 may be configured of one stage. An overcurrent protection circuit 800b may also be applied to the power amplifier 1000b configured of one stage.

The overcurrent protection circuit 800b may detect a voltage corresponding to a magnitude of the output RF signal of the power transistor 200, and may sink a current as much as the current Iₛᵢₙₖ from the second bias circuit 720 when the detected voltage is greater than a set value. As a result, the bias current I_{BIAS2} supplied to the power transistor 200 may be reduced.

As described above, the overcurrent protection circuit 800b is also applied to the power amplifier 1000b configured of one stage, so that overcurrent may be prevented from flowing through the power transistor 200.

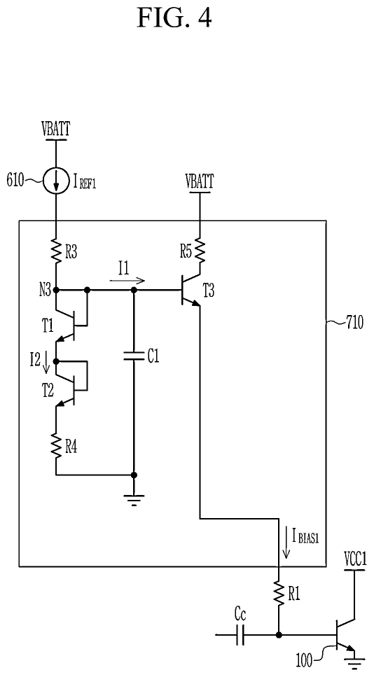

FIG. 4 illustrates an example of the first bias circuit 710 shown in FIG. 1.

Referring to FIG. 4, the first bias circuit 710 may include a first transistor T1, a second transistor T2, a third transistor T3, a first resistor R3, a second resistor R4, a third resistor R5, and a capacitor C1.

In an example, the transistors T1, T2, and T3 may be implemented as various transistors such as, but not limited to, a heterojunction bipolar transistor (HBT), a bipolar junction transistor (BJT), and an insulated gate bipolar transistor (IGBT). Additionally, although the transistors T1, T2, and T3 are shown as n-type transistors in FIG. 4, this is only an example, and they may be replaced with p-type transistors. Additionally, in FIG. 4, a contact point connected to a base of the transistor T3 and being between a base and a collector of the transistor T1 is indicated as a node N3.

The base and the collector of the transistor T1 may be connected to the node N3, and the collector of the transistor T1 may be connected to a current source, for example a first reference current generating circuit 610 that supplies a reference current I_{REF1}. The transistor T1 may have a diode-connection structure. The resistor R3 may be connected between the collector of the transistor T1 and the current source, for example the first reference current generating circuit 610. Since the first reference current generating circuit 610 supplies the reference current I_{REF1} to the first bias circuit 710, the first reference current generating circuit 610 is indicated as the current source 610 in FIG. 4.

A base and a collector of the transistor T2 may be connected to each other, and the collector of the transistor T2 may be connected to an emitter of transistor T1. The transistor T2 may have a diode-connection structure, and an emitter of the transistor T2 may be connected to the ground. In an example, the resistor R4 may be additionally connected between the emitter of the transistor T2 and the ground.

The transistor T1 and the transistor T2 may sink a current as much as a current I2 from the reference current I_{REF1}.

A collector of the transistor T3 may be connected to a power source voltage VBATT. In an example, the resistor R5 may be additionally connected between the collector of the transistor T3 and the power source voltage VBATT. The base of the transistor T3 may be connected to the node N3. Additionally, an emitter of the transistor T3 may be connected to the input terminal or base of the driver transistor 100, via resistor R1, and may supply the bias current I_{BIAS1} to the driver transistor 100.

The reference current I_{REF1} is divided into a current I1 and a current I2, and the current I1 may be inputted to the base of the transistor T3. Since the bias current I_{BIAS1} generated by the first bias circuit 710 corresponds to the base current of the driver transistor 100, the bias current I_{BIAS1} and the current flowing through the driver transistor 100 may have a relationship of Equation 1 below.

$${I}_{BIAS 1} = \frac{{I}_{C}}{β} \qquad Equation 1$$

In an example, I_{C} represents a current flowing through the driver transistor 100, and ß represents a common-emitter current gain of the driver transistor 100.

Referring to Equation 1, when the bias current I_{BIAS1} increases, the current flowing through the driver transistor 100 also increases. When the bias current I_{BIAS1} decreases, the current flowing through the driver transistor 100 also decreases.

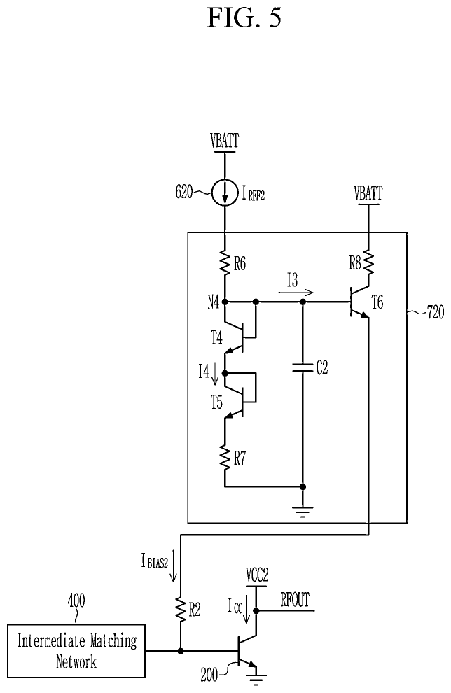

FIG. 5 illustrates an example of the second bias circuit 720 shown in FIG. 1.

Referring to FIG. 5, the second bias circuit 720 may include a fourth transistor T4, a fifth transistor T5, a sixth transistor T6, a resistor R6, a resistor R7, a resistor R8, and a capacitor C2.

The transistors T4, T5, and T6 may be implemented as various transistors such as, but not limited to, a heterojunction bipolar transistor (HBT), a bipolar junction transistor (BJT), and an insulated gate bipolar transistor (IGBT). Additionally, although the transistors T4, T5, and T6 are shown as n-type transistors in FIG. 5, they may be replaced with p-type transistors. Additionally, in FIG. 5, a contact point connected to a base of the transistor T6 and disposed between a base and a collector of the transistor T4 is indicated as a node N4.

The second bias circuit 720 may have a configuration that is similar to the configuration of the first bias circuit 710.

The second bias circuit 720 receives the reference current I_{REF2} from the second reference current generating circuit 620, and generates the bias current I_{BIAS2}. The reference current I_{REF2} is divided into a current I3 and a current I4, and the current I3 may be inputted to the base of the transistor T4 and the base of the transistor T6. Since the bias current I_{BIAS2} corresponds to the base current of the power transistor 200, the bias current I_{BIAS2} and the current flowing through the power transistor 200 may have a relationship of Equation 2 below.

$${I}_{BIAS 2} = \frac{{I}_{CC}}{β} \qquad Equation 2$$

In Equation 2, I_{CC} represents a current flowing through the power transistor 200, and β represents a common-emitter current gain of the power transistor 200.

Referring to Equation 2, when the bias current I_{BIAS2} increases, the current I_{CC} flowing through the power transistor 200 also increases. When the bias current I_{BIAS2} decreases, the current I_{CC} flowing through the power transistor 200 also decreases.

In this example, the overcurrent protection circuit 800 according to the embodiment may detect the voltage of the output RF signal of the driver transistor 100 that amplifies and outputs the input RF signal RFIN, and may reduce the bias current I_{BIAS2} by sinking a current as much as the current Iₛᵢₙₖ from the second bias circuit 720 when the voltage of the output RF signal is greater than or equal to a set value. Additionally, as the bias current I_{BIAS2} is reduced, the current I_{CC} flowing through the power transistor 200 is also reduced, so an overcurrent may be prevented from flowing through the power transistor 200. The overcurrent protection circuit 800 performing this operation will be described in detail below.

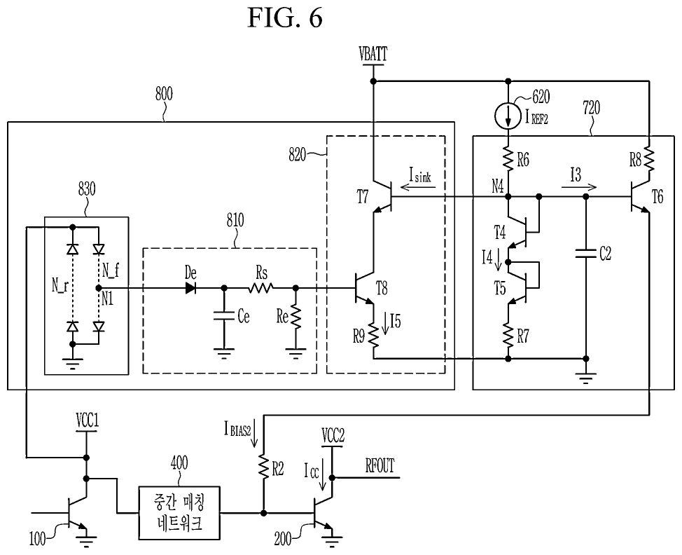

FIG. 6 illustrates the example overcurrent protection circuit 800 shown in FIG. 1.

Referring to FIG. 6, the overcurrent protection circuit 800 may include an envelope detector 810 and a protection circuit part 820. The overcurrent protection circuit 800 may further include an electrostatic discharge (ESD) protecter 830.

The envelope detector 810 may detect the envelope of the output RF signal of the driver transistor 100 corresponding to the input RF signal RFIN. Additionally, the envelope detector 810 may output a control signal to the protection circuit part 820 to operate the protection circuit part 820 when the value of the detected envelope is greater than or equal to a set value. In an example, the control signal is a signal to turn on a transistor T8 of the protection circuit part 820, and may be a signal applied to a base of the transistor T8.

The envelope detector 810 includes a diode De, a capacitor Ce, a resistor Re, and a resistor Rs.

An anode of the diode De may be connected to the output terminal of the driver transistor 100, and a cathode of the diode De may be connected to a first end of the capacitor Ce. Additionally, the cathode of the diode De may be connected to a first end of the resistor Rs. A second end of the capacitor Ce may be connected to the ground. A second end of the resistor Rs may be connected to the base of the transistor T8 of the protection circuit part 820. Additionally, the second end of the resistor Rs may be connected to a first end of the resistor Re, and the second end of the resistor Re may be connected to the ground.

When a voltage of the output RF signal of the driver transistor 100 is a positive voltage, the diode De may be turned on, and a current passing through the diode De may be charged in the capacitor Ce. That is, the envelope of the output RF signal of the driver transistor 100 may be detected by the diode De and the capacitor Ce. The voltage charged in the capacitor Ce may be divided by the resistor Rs and the resistor Re, and the divided voltage may be applied to the base of the transistor T8 of the protection circuit part 820. In this example, when the divided voltage is a turn on voltage of the transistor T8, the transistor T8 may be turned on.

According to the embodiment, when the envelope value of the output RF signal of the driver transistor 100 is greater than a set value, the transistor T8 may be turned on by the voltage divided by the resistor Rs and the resistor Re. That is, when the envelope value of the output RF signal of the driver transistor 100 is less than the set value, the transistor T8 may be turned off. When the envelope value of the output voltage of the driver transistor 100 is equal to or greater than the set value, it may mean that an excessive input RF signal RFIN is applied. In this case, through the resistor Rs, when the envelope value of the output RF signal of the driver transistor 100 is greater than the set value, the turn on voltage of the transistor M8 may be set so that the transistor T8 is turned on, and the set value may be adjusted by adjusting the resistance value of the resistor Rs.

The protection circuit part 820 may include a transistor T7, a transistor T8, and a resistor R9.

The collector of the transistor T7 may be connected to the power source voltage VBATT, and the base of the transistor T7.may be connected to the node N4 of the second bias circuit 720. That is, the base of the transistor T7 may be connected to the base of the transistor T6 of the second bias circuit 720.

A collector of the transistor T8 may be connected to an emitter of transistor T7, and an emitter of transistor T8 may be connected to the ground. A base of the transistor T8 may be connected to the envelope detector 810. That is, the base of the transistor T8 may be connected to the contact point between the resistor Rs and the resistor Re. Therefore, the transistor T8 may be turned on by the voltage divided by the resistor Rs and the resistor Re. Additionally, the resistor R9 may be additionally connected between the emitter of the transistor T8 and the ground.

When the transistor T8 is turned on, a current I5 flows through the transistor T7 and transistor T8. In this example, since the base of the transistor T7 is connected to the node N4 that is, the base of the transistor T6 of the second bias circuit 720, the reference current I_{REF2} may have a relationship of Equation 3 below with the currents I3, I4, and Iₛᵢₙₖ.

$${I}_{REF 2} = I 3 + I 4 + {I}_{sink} \qquad Equation 3$$

When the transistor T8 is turned on, the current Iₛᵢₙₖ is generated. Assuming that the reference current I_{REF2} is constant, the current I3 and/or the current I4 may decrease as the current Iₛᵢₙₖ is generated. According to the embodiment, when the transistor T8 is turned on, the transistor T8 may sink a predetermined current from the current I3. For example, the current I4 may have a fixed value. Assuming that the current I4 has a fixed value, when the transistor T8 is turned on, it may sink a current as much as the current Iₛᵢₙₖ from the current I3. Accordingly, the current I3 may be decreased, and the bias current I_{BIAS2} may also be decreased.

When the input RF signal RFIN increases, the envelope value of the RF output signal of the driver transistor 100 detected by the envelope detector 810 increases. Accordingly, since more current is transmitted to the base of the transistor T8, the current I5 increases, the sink current Iₛᵢₙₖ transmitted to the base of the transistor T7 increases. As the sink current Iₛᵢₙₖ creases, the current I3 applied to the base of the transistor T6 decreases according to, and the bias current I_{BIAS2} applied to the base of the power transistor 200 also decreases. an overcurrent may be prevented from flowing through the power transistor 200.

In this way, the overcurrent protection circuit 800 sinks the current Iₛᵢₙₖ from the bias circuit 720 in response to the envelope value of the RF output signal of the driver transistor 100, so that even if an excessive input RF signal RFIN is applied, an overcurrent may be prevented from flowing through the power transistor 200.

Meanwhile, the ESD protector 830 may be connected between the output terminal (that is, the collector) of the driver transistor 100 and the envelope detector 810.

The ESD protector 830 may include a diode stack N_r and a diode stack N_f. The diode stack N_r and the diode stack N_f have a structure in which a plurality of diodes are coupled in series. The diode stack N_r and the diode stack N_f may be connected in parallel to each other. A cathode of the diode stack N_r may be connected to the output terminal of the driver transistor 100, and an anode of the diode stack N_r may be connected to the ground. An anode of the diode stack N_f may be connected to the output terminal of the driver transistor 100, and a cathode of the diode stack N_f may be connected to the ground. The ESD protector 830 may lower the voltage of the RF output signal of the driver transistor 100 to an appropriate voltage based on the fact that a voltage drop occurs when a current passes through one diode. In this example, a contact point between two diodes in the diode stack N_f is indicated as a node N1. The node N1 may be an output terminal of the ESD protector 830. That is, the node N1 may be connected to the anode of the diode De.

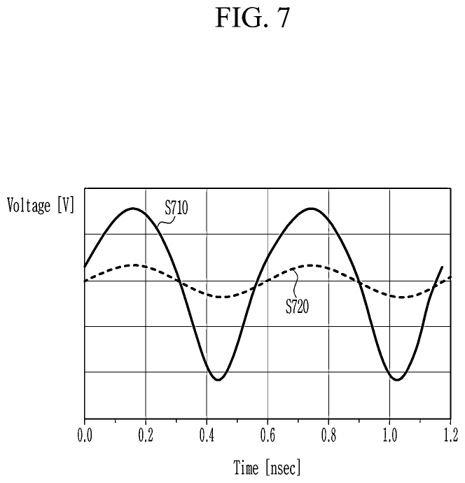

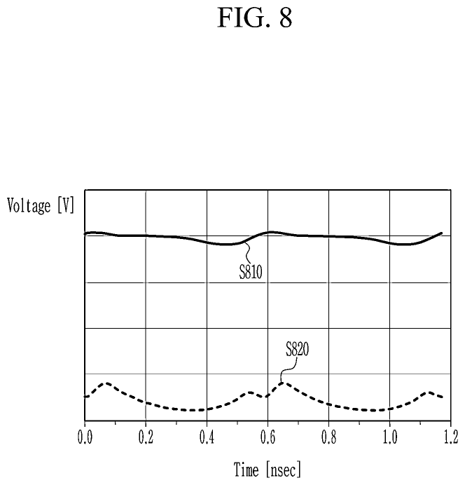

FIG. 7 illustrates an example input RF signal waveform applied to the base of the driver transistor shown in FIG. 1, and FIG. 8 illustrates an example envelope detected by the envelope detector shown in FIG. 6.

In FIG. 7, S710 represents an input RF signal waveform having a power of 15 dBm, and may be an input RF signal waveform corresponding to a severe condition outside a normal operating range of the power amplifier 1000. S720 represents an input RF signal waveform having a power of 2 dBm.

Referring to FIG. 7, as the power of the input RF signal RFIN increases, voltage swing of the input RF signal RFIN increases.

An output RF signal of the driver transistor 100 corresponding to the input RF signal RFIN may be converted into a voltage waveform as shown in FIG. 8 while passing through the envelope detector 810.

In FIG. 8, S810 represents an envelope waveform of the envelope detector 810 for an input RF signal waveform having a power of 15 dBm. S820 represents an envelope waveform of the envelope detector 810 for an input RF signal waveform having a power of 2 dBm.

Referring to FIG. 7 and FIG. 8, it can be seen that the envelope voltage detected by the envelope detector 810 increases as the power of the input RF signal RFIN increases.

In this example, the envelope voltage level of the envelope detector 810 may be adjusted by adjusting the value of the resistor Rs. Accordingly, the turn on voltage level of the transistor T8 may be adjusted. That is, by adjusting the value of the resistor Rs, the transistor T8 may be set to be turned on for an input RF signal RFIN outside the normal operating range of the power amplifier 1000.

For example, the transistor T8 may be turned on by an envelope value of the envelope detector 810 corresponding to an input RF signal RFIN having a power of 15 dBm. On the other hand, the transistor T8 may not be turned on by an envelope value of the envelope detector 810 corresponding to an input RF signal RFIN having a power of 2 dBm.

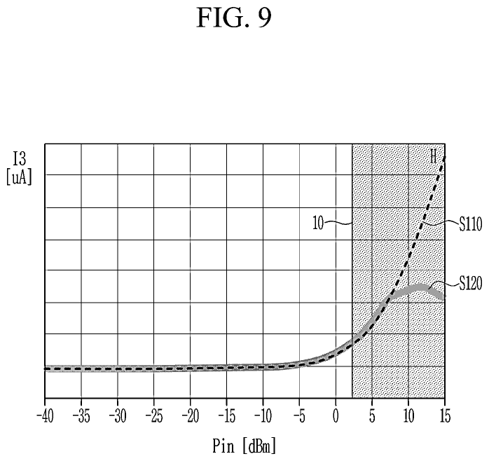

The effect of the overcurrent protection circuit 800 shown in FIG. 6 in the power amplifier 1000 shown in FIG. 1 will be described with reference to FIG. 9 to FIG. 13.

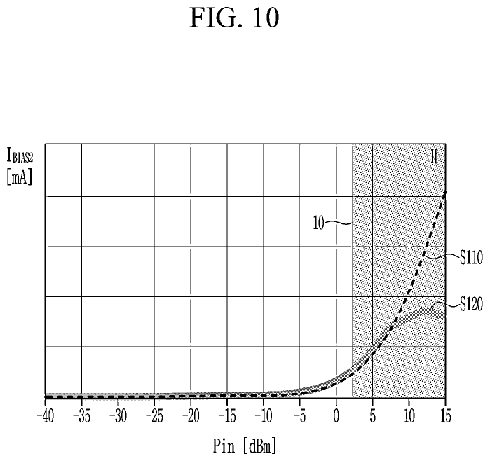

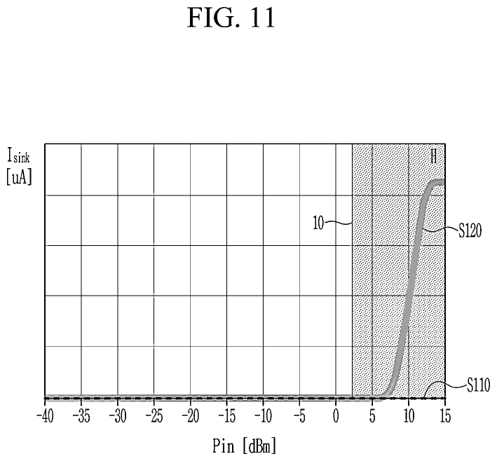

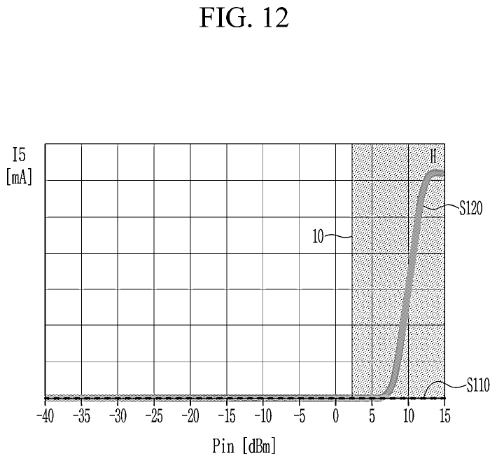

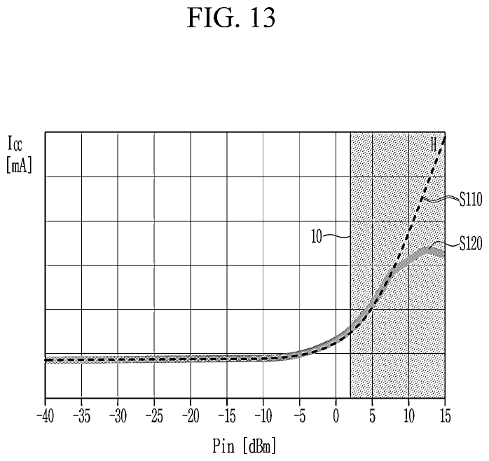

FIG. 9 illustrates a graph of a simulation result for the current I3 shown in FIG. 6, and FIG. 10 illustrates a graph of a simulation result for the bias current I_{BIAS2} shown in FIG. 6. FIG. 11 illustrates a graph of a simulation result for the current Iₛᵢₙₖ shown in FIG. 6, and FIG. 12 illustrates signal graph of a simulation result for the current I5 shown in FIG. 6. FIG. 13 illustrates a graph of a simulation result for the current I_{CC} shown in FIG. 6.

In FIG. 9 to FIG. 13, S110 is a comparative example, and represents a simulation result for a power amplifier without the overcurrent protection circuit 800. S120 represents a simulation result of the power amplifier 1000 including the overcurrent protection circuit 800 as an example.

Referring to S110 of FIG. 9 and FIG. 10, in the comparative example, it can be seen that as a power Pin of the input RF signal RFIN increases, the current I3 applied to the base of the transistor T6 also increases, and accordingly, the bias current I_{BIAS2} also increases. Particularly, it can be seen that in a range 10 outside the normal operating range, the current I3 and the bias current I_{BIAS2} rapidly increase as the power Pin of the input RF signal RFIN increases.

On the other hand, referring to S120 of FIG. 9 and FIG. 10, in the example, it can be seen that in the range 10 outside the normal operating range, even when the input RF signal RFIN having high power is inputted, the current I3 applied to the base of the transistor T6 does not increase any more, and the bias current I_{BIAS2} also no longer increases.

Additionally, referring to S120 of FIG. 11 and FIG. 12, in the example, it can be seen that in the range 10 outside the normal operating range, as the power Pin of the input RF signal RFIN increases, the current Iₛᵢₙₖ and the current I5 increases.

That is, when the input RF signal RFIN having power outside the normal operating range is inputted, the transistor T8 of the overcurrent protection circuit 800 is turned on to sink the current I3 applied to the base of the transistor T6. Accordingly, the current I3 and the bias current I_{BIAS2} decreases, and the current Iₛᵢₙₖ and the current I5 increases.

As a result, referring to S120 of FIG. 13, in the example, it can be seen that even if the power Pin of the input RF signal RFIN increases in the range 10 outside the normal operating range, the current I_{CC} flowing through the output terminal (that is, the collector) of the power transistor 200) does not increase any more.

On the other hand, referring to S110 of FIG. 13, in the comparative example, it can be seen that as the power Pin of the input RF signal RFIN increases in the range 10 outside the normal operating range, the current I_{CC} flowing through the output terminal (that is, the collector) of the power transistor 200) significantly increases. That is, without the overcurrent protection circuit 800, the power transistor 200 is highly likely to be burned by the input RF signal RFIN of the high power Pin.

As described above, in the power amplifier 1000 according to the embodiment, it is possible to protect the power amplifier 1000 from the overcurrent even when the input RF signal RFIN of excessive power is inputted through the overcurrent protection circuit 800.

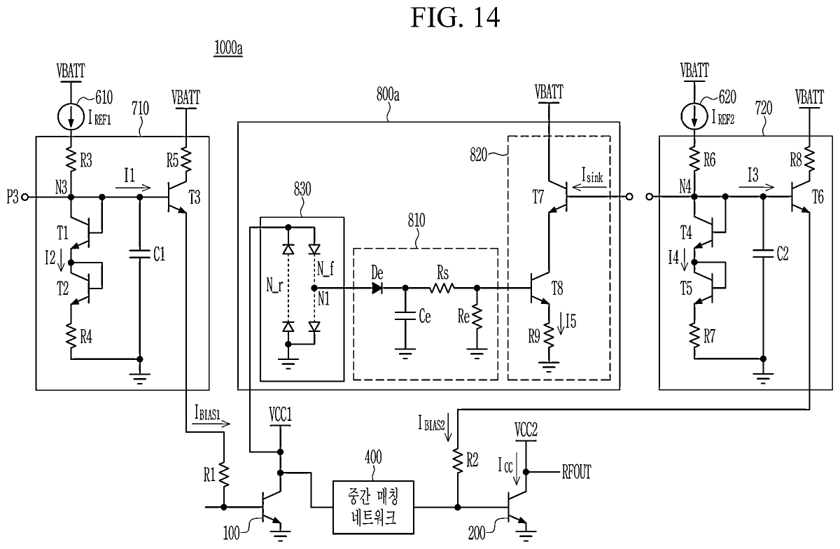

FIG. 14 illustrates the example overcurrent protection circuit 800a shown in FIG. 2.

Referring to FIG. 14, the overcurrent protection circuit 800a may have a configuration similar to the configuration of the overcurrent protection circuit 800 shown in FIG. 6.

However, a base of a transistor T7 may be both connected to the node N3 corresponding to the base of the transistor T3 of the first bias circuit 710 and the node N4 corresponding to the base of the transistor T6 of the second bias circuit 720.

Accordingly, when the input RF signal RFIN having power outside the normal operating range is inputted, a transistor T8 in the overcurrent protection circuit 800a is turned on. When the transistor T8 is turned on, a current Iₛᵢₙₖ from the current I1 applied to the base of the transistor T3 and the current I3 applied to the base of the transistor T6 may be sunk to the base of the transistor T7. Accordingly, the overcurrent protection circuit 800a may simultaneously reduce the bias current I_{BIAS1} applied to the base of the driver transistor 100 and the bias current I_{BIAS2} applied to the base of the power transistor 200.

Accordingly, the overcurrent protection circuit 800a may be applied even to a multi-stage power amplifier configured of three or more stages.

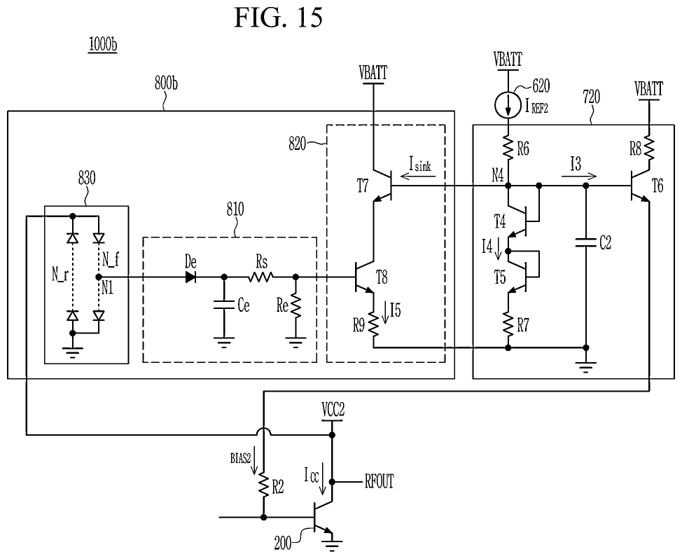

FIG. 15 illustrates the example overcurrent protection circuit 800b shown in FIG. 3.

Referring to FIG. 15, the overcurrent protection circuit 800b may have a configuration similar to the configuration of the overcurrent protection circuit 800 shown in FIG. 6.

However, an input terminal of an ESD detector 830 of the overcurrent protection circuit 800b may be connected to the output terminal (that is, the collector) of the power transistor 200, and a base of the transistor T7 of the overcurrent protection circuit 800b may be connected to the node N4 of the second bias circuit 720.

The current protection circuit 800b may detect the voltage corresponding to the output RF signal of the power transistor 200, and may sink a current as much as the current Iₛᵢₙₖ from the second bias circuit 720 to reduce the bias current I_{BIAS2} supplied to the power transistor 200 when the detected voltage is equal to or greater than a set value.

While this disclosure includes specific examples, it will be apparent to one of ordinary skill in the art, after an understanding of the disclosure, that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, the scope of the disclosure is defined not by the detailed description, but by the claims and their equivalents, and all variations within the scope of the claims and their equivalents are to be construed as being included in the disclosure.

What is claimed is:

1. A power amplifier overcurrent protection circuit, the overcurrent protection circuit comprising:
an envelope detector configured to detect an envelope for a first voltage corresponding to an input radio frequency (RF) signal;
a first transistor configured to receive a value of the envelope through a control terminal of the first transistor and turn on based on the value of the envelope to sink a current from a first node of a bias circuit; and
a second transistor connected between a power source and the first transistor and including a control terminal connected to the first node of the bias circuit.

2. The overcurrent protection circuit of claim 1, wherein:
the bias circuit comprises a third transistor configured to supply the bias current, and
the first node is connected to a control terminal of the third transistor.

3. The overcurrent protection circuit of claim 2, wherein:
the bias circuit further comprises a fourth transistor and a fifth transistor that are stacked between the first node and a ground.

4. The overcurrent protection circuit of claim 1, wherein:
the envelope detector comprises a first resistor configured to adjust a turn-on voltage level of the first transistor from an envelope for the first voltage.

5. The overcurrent protection circuit of claim 4, wherein:
the envelope detector further comprises:
a diode, wherein the first voltage is inputted to an anode of the diode, and a cathode of the diode is connected to a first terminal of the first resistor;
a capacitor, wherein a first terminal of the capacitor is connected to the cathode of the diode, and a second terminal of the capacitor is connected to a ground; and
a second resistor connected between a second terminal of the first resistor and the ground, and
the second terminal of the first resistor is connected to the control terminal of the first transistor.

6. The overcurrent protection circuit of claim 1, wherein:
the power amplifier comprises:
a power transistor configured to amplify and output the input RF signal;
wherein a first voltage corresponding to the input RF signal is a voltage of an RF signal amplified by the power transistor; and
wherein the bias circuit is configured to supply the bias current to the power transistor.

7. The overcurrent protection circuit of claim 1, wherein:
the power amplifier comprises:
a driver transistor configured to receive a first bias current and amplify and output the input RF signal; and
a power transistor configured to receive a second bias current and amplify and output an RF signal amplified by the driver transistor, and
wherein a first voltage corresponding to the input RF signal is a voltage of an RF signal amplified by the driver transistor.

8. The overcurrent protection circuit of claim 7, wherein:
the bias circuit comprises:
a first bias circuit configured to supply the first bias current; and
a second bias circuit configured to supply the second bias current, and
wherein the first transistor is configured to turn on based on the envelope value to sink a current from the first bias circuit and the second bias circuit.

9. The overcurrent protection circuit of claim 8, wherein:
the first bias circuit comprises a third transistor configured to supply the first bias current;
the second bias circuit comprises a fourth transistor configured to supply the second bias current; and
the control terminal of the second transistor is connected to a control terminal of the third transistor and a control terminal of the fourth transistor.

10. A power amplifier, comprising:
a first transistor configured to amplify a radio frequency (RF) signal;
a first bias circuit comprising a second transistor configured to supply a first bias current to the first transistor;
an envelope detector configured to detect an envelope for a first voltage corresponding to the RF signal; and
a protection circuit part configured to reduce the first bias current by sinking a current from the first bias circuit when a value of the envelope is equal to or greater than a set value,
wherein the protection circuit part comprises:
a third transistor configured to receive the value of the envelope through a control terminal of the third transistor, and including a first terminal, and a second terminal connected to a ground; and
a fourth transistor including a control terminal connected to a control terminal of the second transistor, a first terminal connected to a power source, and second terminal connected to the first terminal of the third transistor.

11. The power amplifier of claim 10, further comprising:
a fifth transistor configured to amplify the RF signal, and transmit the RF signal to the first transistor; and
a second bias circuit comprising a sixth transistor configured to supply a second bias current to the fifth transistor,
wherein the first voltage corresponding to the input RF signal is a voltage of an RF signal amplified by the fifth transistor.

12. The power amplifier of claim 11, wherein:
the control terminal of the fourth transistor is connected to a control terminal of the second transistor and a control terminal of the sixth transistor.

13. The power amplifier of claim 10, wherein:
the first voltage corresponding to the input RF signal is a voltage of an RF signal amplified by the first transistor.

14. The power amplifier of claim 10, wherein:
the envelope detector comprises a resistor configured to adjust a turn-on voltage level of the third transistor from an envelope for the first voltage.

15. The power amplifier of claim 10, wherein:
the first bias circuit further comprises a fifth transistor and a sixth transistor that are stacked between a control terminal of the second transistor and the ground.

16. A power amplifier, comprising:
a first transistor and a second transistor configured to amplify an input radio frequency (RF) signal;
one or more bias circuits configured to generate bias currents, and supply the generated bias currents to the first transistor and the second transistor;
an envelope detector, configured to detect a voltage of an output RF signal of the first transistor or an output RF signal of the second transistor; and
a protection circuit, comprising a third transistor, and configured to sink a current from the one or more bias circuits when the detected voltage is greater than or equal to a predetermined value;
wherein a control terminal of the third transistor is connected to an output terminal of the envelope detector.

17. The power amplifier of claim 16, wherein the envelope detector includes a resistor that is connected the control terminal of the third transistor, and the resistor is configured to adjust a turn-on voltage of the third transistor.

18. The power amplifier of claim 16, wherein the protection circuit includes a fourth transistor including a control terminal to which the current sunk from the at least one bias circuit is input, a first terminal connected to a first terminal of the third transistor, and a second terminal connected to a power source.
